(19) United States
(12) Patent Application Publication
(10) Pub. No.: US 2008/0138993 A1
(43) Pub. Date: Jun. 12, 2008

(54) Plasma Processing Apparatus

(76) Inventors: Mitsuru Hiroshima, Osaka (JP); Sumio Miyake, Kyoto (JP); Mitsuhiro Okune, Nara (JP); Shozoh Watanabe, Osaka (JP); Hiroyuki Suzuki, Osaka (JP)

Correspondence Address: WENDEROTH, LIND & PONACK L.L.P., 2033 K. STREET, NW, SUITE 800, WASHINGTON, DC, 20006, US

(21) Appl. No.: 11/794,306

(22) PCT Filed: Dec. 6, 2005
(86) PCT No.: PCT/JP05/22353

§ 371 Date: Aug. 29, 2007

(30) Foreign Application Priority Data
Dec. 28, 2004 (JP) 2004-380279

(51) Int. Cl. H01L 21/3065

(52) U.S. Cl. 438/714; 156/345.35; 257/E21.218

(57) ABSTRACT

A dry etching apparatus comprises: a vacuum chamber where a processing target is disposed on a bottom wall side of an internal space; a coil for generating plasma that is disposed above and outside the vacuum chamber and has conductors disposed so that a gap is formed in a plane view; a top wall that closes the top of the internal space and has a transparent section at a position corresponding to the gap between conductors of the coil 36 in the plane view; and a camera that is disposed above the coil and can capture at least a part of the processing target in a field of view through the gap and the transparent section. The status of the processing target during plasma processing can be observed in real-time.

### TECHNICAL FIELD

The present invention relates to a plasma processing apparatus.

### BACKGROUND ART

As the semiconductor industry develops, various proposals are being made for plasma processing apparatuses, such as dry etching apparatuses and sputtering apparatuses. Patent Publication 1, for example, discloses that a CCD camera is embedded in a lower electrode of a plasma processing apparatus, and an image of plasma generated in a chamber is taken in a status where a processing target has not yet been mounted on the lower electrode.

When holes, such as trenches and via holes, are formed in a processing target by a dry etching apparatus, if an image of etched surfaces constituting bottoms of the trenches and holes can be taken, and then whether etching residues are generated or not can be observed in real-time, and thus the process conditions can be controlled based on the observation. For example, in the case of the dry etching of a processing target made of a silicon material, a phenomena where an SiO₂ (silicon dioxide) deposit, which is a reaction product during etching, is deposited on the etching surface and remains as etching residue may occur (black silicon phenomena). If the generation of this black silicon phenomena can be monitored in real-time during etching, the process conditions can be changed according to the monitoring. However, the CCD camera embedded in the lower electrode as disclosed in Patent Publication 1 can not observe the processing target during etching.

[Patent Publication 1] Japanese Patent Application Laid-Open Publication No. 2002-93788

### DISCLOSURE OF THE INVENTION

### Problem to be Solved by the Invention

An object of the present invention is to provide a plasma processing apparatus that can observe a status of a processing target in real-time.

### Means for Solving the Problem

The present invention provides a plasma processing apparatus, comprising, a vacuum chamber in an internal space of which a processing target is disposed at a bottom wall side, a coil for generating plasma disposed outside and above the vacuum chamber and provided with conductors arranged so that a gap is formed in a plane view, a top wall of the vacuum chamber closing a top of the internal space and provided with a transparent section at a position corresponding to the gap between the conductors of the coil in the plane view, and an imaging device disposed above the coil and being capable of putting at least a part of the processing target in the internal space of the vacuum chamber into a field of view thereof through the gap between the conductors of the coil and the transparent section of the top wall.

The imaging device can put the processing target in the vacuum chamber into the view field through the gap of the coil and the transparent section of the top wall. Thus, the processing target can be captured even after the processing target is placed in the internal space and the internal space is closed by the top wall. In other words, the imaging device can capture the processing target during plasma processing. Therefore, the status of the processing target during plasma processing in the vacuum chamber can be observed in real-time by the image captured by the imaging device.

If the wall comprises a plate made of quartz, it is preferable that the transparent section is formed by polishing at least an outer surface of the plate opposing to the inner space at the portion corresponding to the gap between the conductors of the coil in the plane view. The transparency further improves by polishing an inner surface of the plate located at the internal space side at the portion corresponding to the gap between the conductors of the coil in the plane view.

If continuously exposed to plasma, the inner surface of the plate made of quartz is gradually etched. Therefore even if the inner face of the plate made of quartz is polished, a drop in transparency or fogging is generated if the status of being exposed to plasma continues. In order to prevent the drop in transparency or fogging, it is preferable that the transparent section further comprises a window plate made of sapphire installed in an inner surface of the plate located at the internal side at the portion corresponding to the gap between the conductors of the coil in the plane view. Sapphire is a material having high transparency, and has strong resistance to a gas generally used for plasma processing, such as F gas, Cl gas, and Br gas. Therefore, in the window plate made of sapphire, the drop in transparency or fogging is not generated even if the status of being exposed to plasma continues.

An alternative is that the top wall has a ceramic substrate having a window section penetrating in the plate thickness direction at which a window plate made of sapphire is disposed.

For alignment of the imaging device with respect to the gap of the coil and the transparent section of the top wall, it is preferable to provide a moving mechanism for horizontally moving the imaging device above the coil. The moving mechanism may move the imaging device automatically, such as an XY table, or move the imaging device manually.

### Effect of the Invention

The top wall of the vacuum chamber of the plasma processing apparatus of the present invention has a transparent section at a position corresponding to the gap between the conductors of the coil in the plane view. The imaging device can put the processing target in the vacuum chamber into filed of view thereof through the gap and transparent section. Therefore the status of the processing target during plasma processing in the vacuum chamber can be observed in real-time using the image captured by the imaging device.

### BRIEF DESCRIPTION OF THE DRAWINGS

FIG. 1 is a schematic cross-sectional view showing a dry etching apparatus according to an embodiment of the present invention;

FIG. 2 is a schematic plane view showing the dry etching apparatus according to the embodiment of the present invention;

FIG. 3 is a schematic partial perspective view showing a dry etching apparatus according to the embodiment of the present invention;

FIG. 4 is a block diagram of the dry etching apparatus according to the embodiment of the present invention;

FIG. 5 is a flow chart for describing the operation of the dry etching apparatus according to the embodiment of the present invention;

FIG. 6 is a diagram showing a target area;

FIG. 7 is a graph showing an example of the relationship between a reference brightness, indication judgment brightness, generated brightness, and measured brightness;

FIG. 8A is a schematic perspective view showing a substrate during etching in a status where the indication of the generation of black silicon is not recognized;

FIG. 8B is a schematic perspective view showing a substrate during etching in a status where the indication of the generation of black silicon is not recognized;

FIG. 9 is a schematic perspective view showing a substrate during etching in a status where the indication of the generation of black silicon is recognized;

FIG. 10 is a cross-sectional view showing a first alternative of the top wall of the vacuum chamber;

FIG. 11A is a cross-sectional view showing a second alternative of the top wall of the vacuum chamber;

FIG. 11B is a bottom view showing the second alternative of the top wall of the vacuum chamber (while the window plate is attached or removed.);

FIG. 11C is a bottom view showing the second alternative of the top wall of the vacuum chamber (when the window plate is attached);

FIG. 12 is a cross-sectional view showing a third alternative of the top wall of the vacuum chamber; and

FIG. 13 is a cross-sectional view showing a fourth alternative of the top wall of the vacuum chamber.

### DESCRIPTION OF REFERENCE NUMERALS

1: substrate.

2: resist mask

7: trench

8: deposit

11: dry etching apparatus

12: vacuum container

13: bottom wall

14: side wall

15: internal space

16: top wall

21: mounting stage

22: lower electrode

23: electric power supply for bias

23a: high frequency AC power supply

23b: matching circuit

24: gas inlet

25: gas supplying section

27: exhaust outlet

28: depressurizing section

29: dielectric plate

30: transparent section

31: upper polished section

32: lower polished section

34: window plate

35: casing

35a: top wall

36: coil

37: conductor

38: electric power supply for coil

38a: high frequency AC power supply

38b: matching circuit

39A, 39B, 39C, 39D: gap

40: casing

41, 42: window hole

45: camera

46: XY table

46a: Y axis slider

46b: Y axis drive motor

46c: X axis slider

46d: X axis drive motor

47: laser light source

49: display section

50: warning light

51: operating/inputting section

54: apparatus control section

55: control section

56: operation condition storage section

57: monitoring section

61: brightness detection section

62: reference brightness storage section

63A: comparison section

64A: judgment section

### BEST MODE FOR CARRYING OUT THE INVENTION

Embodiments of the present invention will be described with reference to the accompanying drawings.

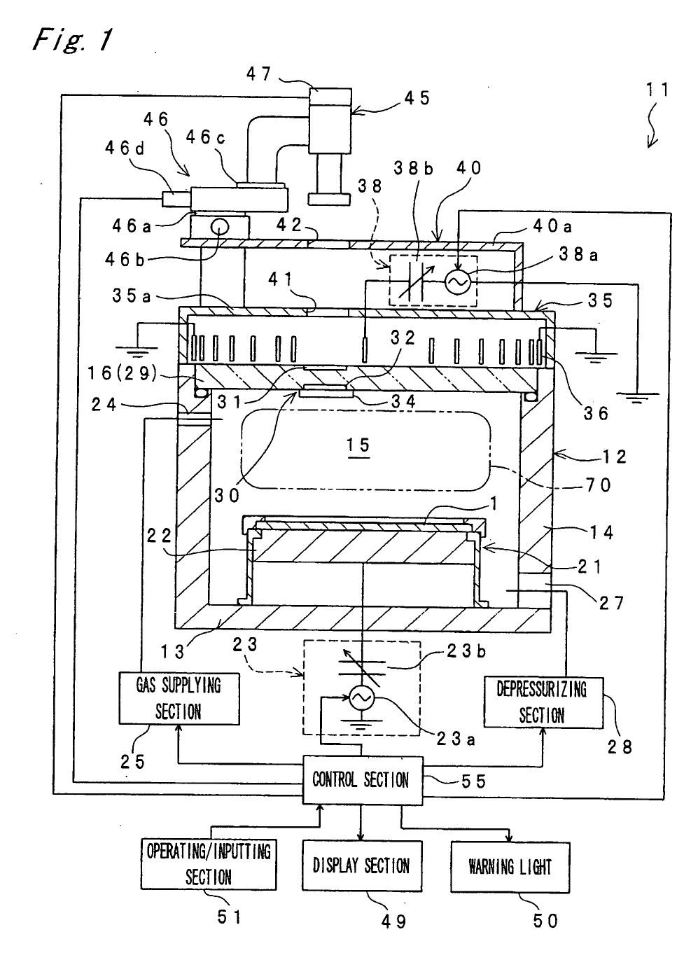

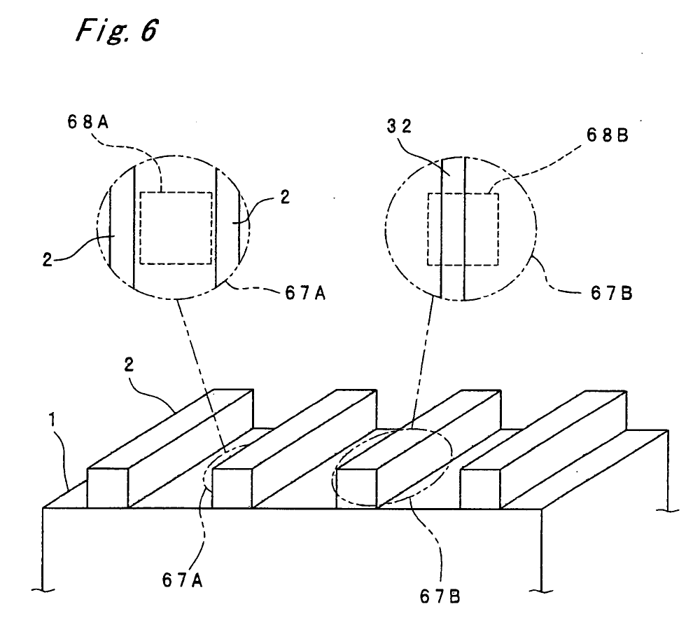

FIGS. 1 to 4 show an inductive coupled type dry etching apparatus 11 according to an embodiment of the present invention. The dry etching apparatus 11 has a chamber or a vacuum container 12. The vacuum container 12 has a bottom wall 13, side walls 14, and top wall 16 which can open and close an internal space 15 of the vacuum container 12. In the internal space 15 of the vacuum container 12, a substrate 1 as a processing target is placed. As shown in FIG. 6, a resist mask 2 is formed on a top face of the substrate 1 in a predetermined pattern. A material of the substrate 1 is a silicon material. The silicon material includes, for example, Si (monocrystal silicon), poly-Si (polysilicon), a-Si (amorphous silicon), WSi (tungsten silicide), MoSi (molybdenum silicide), and TiSi (titanium silicide).

In the internal space 15, a mounting stage 21 for removeably supporting the substrate 1 is disposed at the bottom wall 13 side. The mounting stage 21 has a lower electrode 22, and the substrate 1 is mounted on the top face of the lower electrode 22. The lower electrode 22 is electrically connected to a power supply for bias 23. The power supply for bias 23 has a high frequency AC power supply 23a and a matching circuit 23b for adjusting the impedance.

A gas inlet 24 provided in the vacuum container 12 is connected to a gas supplying section 25 including an MFC (mass flow controller) for supplying etching gas to the internal space 15 of the vacuum container 12 at a desired flow rate. A depressurizing section 28 having a valve, TMP (turbo-molecular pump), and a vacuum pump (e.g. rotary pump, dry pump) is connected to an exhaust outlet 27 provided in the vacuum container 12.

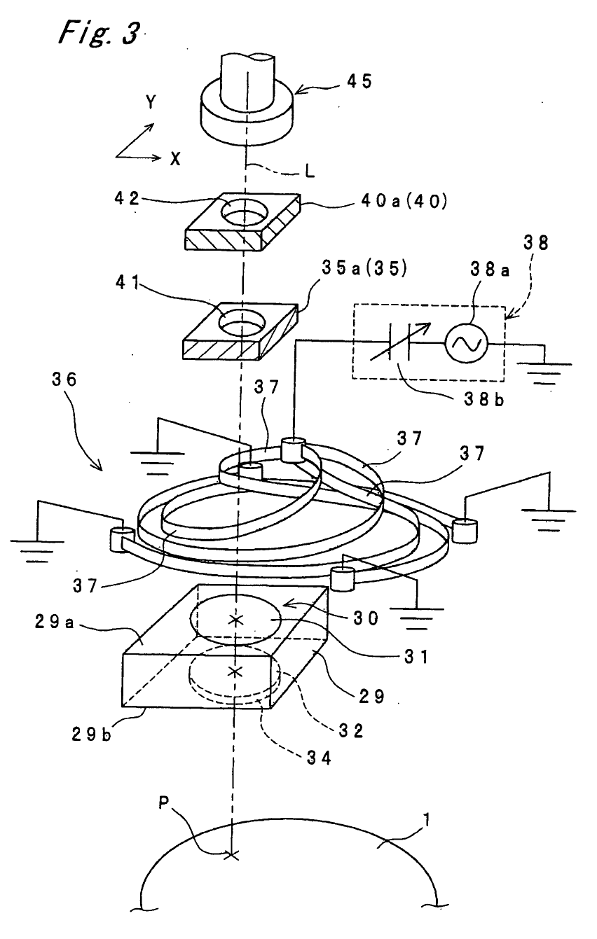

In the present embodiment, the top wall 16 has a dielectric plate (plate) 29 made of quartz. The dielectric plate 29 partially has a portion having transparency in a plate thickness direction, i.e. a transparent section 30. As most clearly shown in FIG. 3, the transparent section 30 has an upper polished section 31 formed by polishing (lapping) a part of the outer face 29a of the dielectric plate 29 (surface opposite from the internal space 15) in a circular shape, and a lower polished section 32 formed by similarly lapping a part of an inner face 29b of the dielectric plate 29 (surface facing the internal space 15) in a circular shape. The positions and areas of the upper polished section 31 and the lower polished section 32 approximately coincides with each other. A disk-like window plate 34 made of sapphire is fixed to the lower polished section 32. The window plate 34 is fixed to an inner face 29b of the dielectric plate 29 by, for example, resin bolts not illustrated. As described later, the sapphire window plate 34 has a function to prevent a drop in transparency or fogging of the transparent section 30 due to the plasma generated during dry etching.

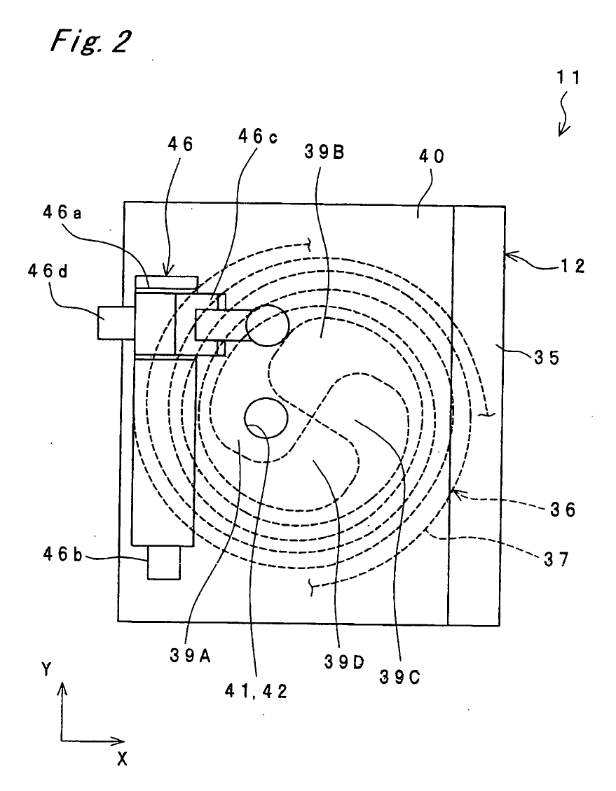

An antenna or coil 36 for generating plasma is accommodated inside a casing 35 having a function of an electromagnetic shield and installed above the vacuum container 12. As shown in FIGS. 2 and 3, the coil 36 is comprised of a plurality of strips of conductors 37 (four in the case of the present embodiment) helically arranged. One end of each conductor 37 is electrically connected to a high frequency power supply for coil 38, and the other end is grounded. The high frequency power supply for coil 38 has a high frequency AC power supply 38a and a matching circuit 38b for adjusting the impedance.

As most clearly show in FIG. 2, the four conductors 37 constituting the coil 36 are arranged so that gaps are formed between them in a plane view. Particularly, in a center area of the coil 36, four gaps having a relatively large area 39A to 39D are formed in a plane view. The above mentioned transparent section 30 of the dielectric plate 29 is formed in a position corresponding to one gap 39A of the four gaps 39A to 39D.

A casing 40 is installed on the casing 35 accommodating the coil 36. The above mentioned high frequency power supply for coil 38 is accommodated inside the casing 40.

As shown in FIGS. 1 and 3, a window hole 41 circular in a plane view is formed in a top wall 35a of the casing 35. In the same way, a window hole 42 circular in a plane view is formed in a top wall 40a of the casing 40. The window holes 41 and 42 are formed at positions corresponding to the gap 39A of the coil 36 in a plane view as same as the transparent section 30 of the dielectric plate 29. The window hole 42 is formed at a position which does not overlap with the high frequency power supply for coil 38 in the casing 40 in a plane view.

As shown in FIGS. 1 and 2, an XY stage (moving mechanism) 46, on which a camera (imaging device) 45 is installed, is mounted on the top wall 40a of the casing 40. Specifically, the XY stage 46 has a Y axis slider 46a moveable along a Y axis direction, and a Y axis drive motor 46b for driving a ball screw mechanism (not illustrated) for moving the Y axis slider 46a. On the Y axis slider 46a, the XY stage 46 also has an X axis slider 46c moveable along an X axis direction and an X axis drive motor 46d for driving a ball screw mechanism (not illustrated) for moving the X axis slider 46c.

A camera 45 is installed on the X axis slider 46c of the XY stage 46, and can move in a horizontal direction (X and Y axis directions) above the coil 36 by the XY stage 46. The camera 45 has an imaging device such as a CCD, and a filed of view thereof is directed downward in a vertical direction. The camera 45 also has a laser light source 47 for measuring distance. The camera 45 also has various functions, including adjustment functions for magnification, focal point, and sensitivity. The image captured by the camera 45 is output to a monitoring section 57 of later mentioned control section 55. The camera 45 can either be a video camera, which can shoot moving images, or a camera which can shoot still images.

A positional relationship of the transparent section 30 of the dielectric plate 29, coil 36, window hole 41 of the casing 35, window hole 42 of the casing 40, and camera 45 will be described with reference to FIG. 3. As described above, the transparent section 30, the window hole 41, and the window hole 42 are all installed at positions corresponding to the gap 39A of the coil 36 in a plane view. Specifically, the transparent section 30, the window hole 41, and the window hole 42 are positioned on a line “L” of the vertical direction indicated by the two dot chain line in FIG. 3. As shown by a point “P”, the lower end of this vertical line “L” reaches a surface of the substrate 1 held on the mounting stage 21. Therefore, if the inside of the dry etching apparatus 11 is looked inside through the window hole 41 of the casing 35, the surface of the substrate 1 can been seen through the window hole 42 of the casing 40, gap 39A of the coil 36, and transparent section 30 of the dielectric plate 29. Because the camera 45 can move in the horizontal direction by the XY stage 46 as mentioned above, the camera 45 can be moved to a position where the field of view of the camera 45 coincides with the vertical line L, that is a position where the substrate 1 of the vacuum container 12 can be put in the field of view through the window hole 41, window hole 42, gap 39A of the coil 36, and transparent section 30 of the dielectric plate 29.

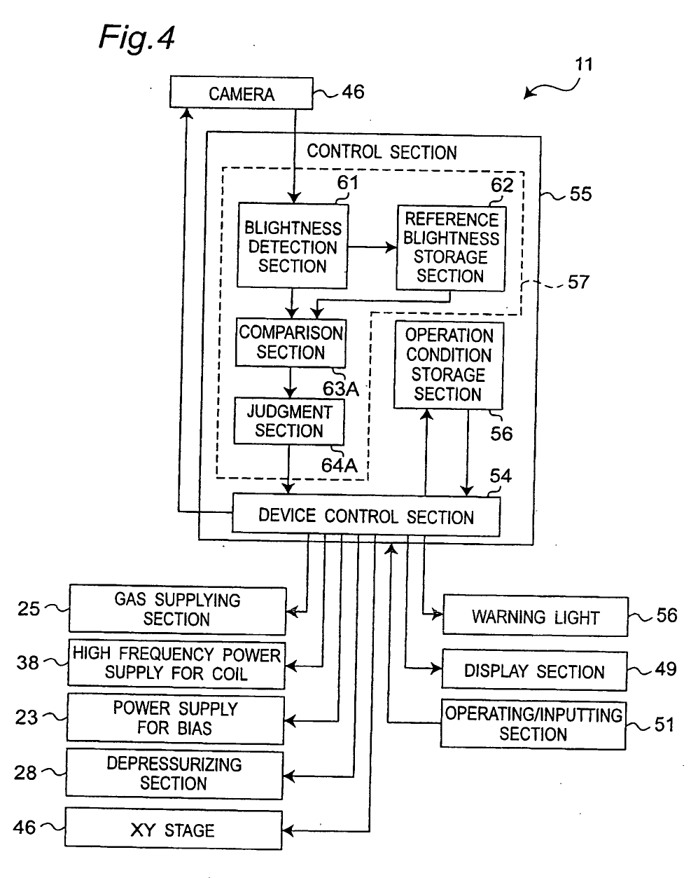

As shown in FIGS. 1 and 4, the dry etching apparatus 11 has a display section 49 which is a liquid crystal display for example, an warning light 50, and an operating/inputting section 51 for an operator to operate the device.

The dry etching apparatus 11 also has a control section 55 for controlling the operation of the entire device, including the gas supplying section 25, depressurizing section 28, high frequency power supply for coil 38, power supply for bias 23, XY stage 46, camera 45, warning light 50, and display section 49. As shown in FIG. 4, the control section 55 has an operation condition storage section 56, apparatus control section 54 and monitoring section 57. The operation condition storage section 56 stores the process conditions for the dry etching to be executed by the dry etching apparatus 11. The process conditions include various conditions, such as a flow rate ratio of a gas contained in the etching gas, bias voltage to be applied to the lower electrode 22 by the power supply for bias 23, and pressure inside the vacuum container 12. Particularly, in the present embodiment, the operation condition storage section 56 stores the process conditions when the indication of the generation of black silicon is detected in addition to the normal process conditions when dry etching is appropriately progressing. The apparatus control section 54 controls the gas supplying section 25, depressurizing section 28, high frequency power supply for coil 38, and power supply for bias 23 according to instructions from the operator which are input from the operating/inputting section 51, and the process conditions stored in the operation condition storage section 56, and executes the dry etching. The apparatus control section 54 also controls the camera 45 and the XY stage 46.

The monitoring section 57 monitors the indication of the generation of black silicon based on the image captured by the camera 45. The monitoring section 57 has a brightness detection section 61, reference brightness storage section 62, comparison section 63A, and judgment section 64A.

The brightness detection section 61 detects etched surface on the surface of the substrate 1 (a bottom of a concave section such as a trench and hole processed by dry etching) based on the image captured by the camera 45. Referring to FIG. 6, within areas on the surface of the substrate 1 included in the field of view of the camera 45, specific areas (target areas) 68A and 68B to be a target of brightness detection are predetermined. The brightness detection section 61 detects the brightness of the target areas 67A and 67B on the surface of the substrate 1. The target area 68A includes only a portion of the surface of the substrate 1 where the resist mask 2 does not exist. The target area 68B partially includes the area of the resist mask 2. Although either the target areas 68A or 68B can be used, it is assumed that the target area 68A is used for brightness detection in the following description. The brightness detection section 61 calculates an in-plane average brightness (measured average brightness Bdet) of the target area 68A from the image on the surface of the substrate 1 captured by the camera 45. In the present embodiment, the measured average brightness Bdet is indicated by 256 grayscales from 0 (darkest) to 255 (brightest) for example.

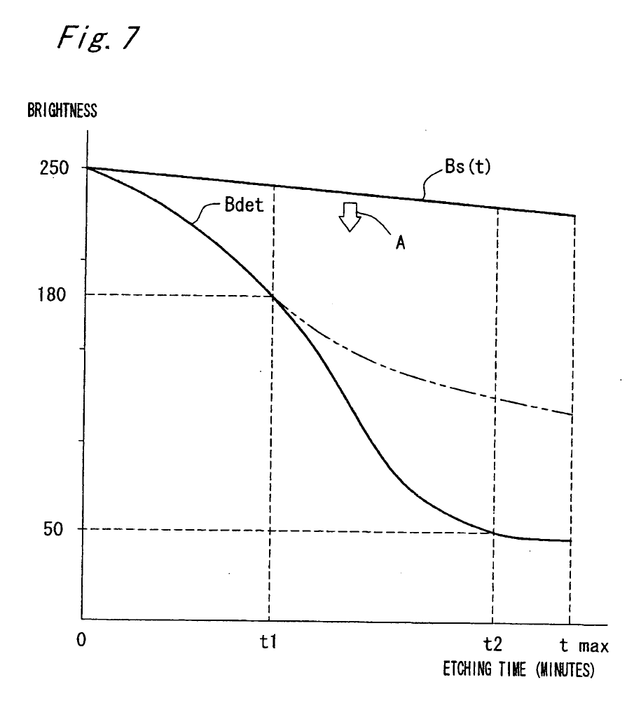

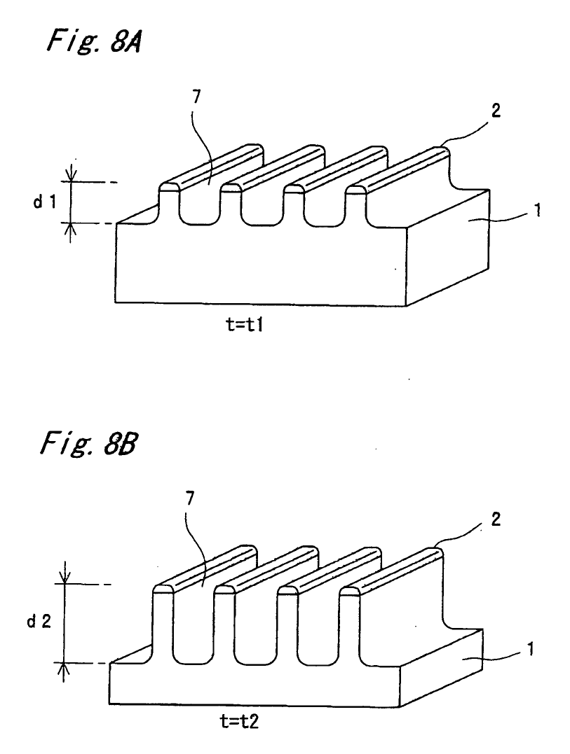

The reference brightness storage section 62 stores the reference brightness Bs(t) for judging the indication of the generation of black silicon in the target area 68A. FIG. 7 shows an example of the reference brightness Bs(t). The reference brightness Bs(t) is a change of the in-plane average brightness of the target area 68A with respect to the elapsed time (etching time) “t” from the etching start in the case when dry etching is completed without generating black silicon. In the example shown in FIG. 7, the reference brightness Bs(t) when dry etching is started (t=0) is 250, and the reference brightness Bs(t) when dry etching ends (t=tmax) is 230, and the reference brightness Bs(t) decreases linearly at a constant rate from the start of etching to the end of etching. The reference brightness Bs(t1) at etching time t1 is 240, and the reference brightness Bs(tmax) at the etching end time tmax is 230. As shown in FIG. 8A, if there is no indication of the generation of black silicon, trenches 7 are formed down to the depth “d1” in an area not covered by the resist mask 2 of the substrate 1 at the etching time t1, and SiO₂ deposit to be the cause of black silicon is not generated in the bottom of the trenches 7. As shown in FIG. 8B, if there is no indication of the generation of black silicon, the trenches 7 are formed down to the depth “d2” at the etching time t2, and SiO₂ deposit is not generated. In the status where there is no indication of the generation of black silicon and a deposit is not generated in the bottom of the trenches 7 as in these cases, the in-plane average brightness of the target area 68A is sufficiently high. In the following description, the reference brightness Bs(t) shown in FIG. 7 is used, but the reference brightness Bs(t) is not limited to this. The reference brightness Bs(t) may be a curve, polygonal line, or step-line for example.

The comparison section 63A compares the measured average brightness Bdet calculated by the brightness detection section 61 and the reference brightness Bs(t) stored in the reference brightness storage section 62. Specifically, the comparison section 63A compares the measured average brightness Bdet of the target area 68A at a certain time “t” with the reference brightness Bs(t) at this time “t”. More specifically, the comparison section 63A calculates a ratio of the measured average brightness Bdet with respect to the reference brightness Bs(t) at a same predetermined time.

The judgment section 64A judges whether there is the indication of the generation of black silicon based on the comparison result by the comparison section 63A. Specifically, the judgment section 64A judges that there is the indication of the generation of black silicon if the ratio of the measured average brightness Bdet with respect to the reference brightness Bs(t) becomes equal to or less than a predetermined ratio (brightness ratio threshold) BRthsy. In the present embodiment, the brightness ratio threshold BRthsy is set to about 0.8 (80%). The condition for that the judgment section 64A judges that there is the indication of the generation of black silicon are shown in the following expression (1).

$$\frac{B det}{B s ( t )} ≦ B R thsy \qquad ( 1 )$$

The judgment section 64A may judge that there is the indication of the generation of black silicon if the measured average brightness Bdet becomes less than the reference brightness Bs(t) by a predetermined brightness in difference (brightness difference threshold) ΔBthsy or more. The condition when the judgment section 64A judges that there is the indication of the generation of black silicon, in this case, are shown in the following expression (2).

Bs(t)−Bdet≦ΔBthsy (2)

In the following description, it is assumed that the brightness ratio threshold BRthsy in the expression (1) is used.

Now a dry etching method using the dry etching apparatus 11 of the present embodiment will be described. As mentioned above, the substrate 1 is made of silicon material. For process conditions, the etching gas supplied from the gas supplying section 25 is SF₆/O₂/He gas, and the flow rates of the SF₆ gas, O₂ gas, and He gas are respectively 60 sccm, 40 sccm, and 1000 sccm (SF₆/O₂/He=60/40/1000 sccm). The power applied from the high frequency power supply for coil 38 to the coil 36 is 1500 W, and the power applied from the power supply for bias 23 to the lower electrode 22 is 80 W. The pressure in the internal space 15 of the vacuum container 12 is maintained to be 30 Pa.

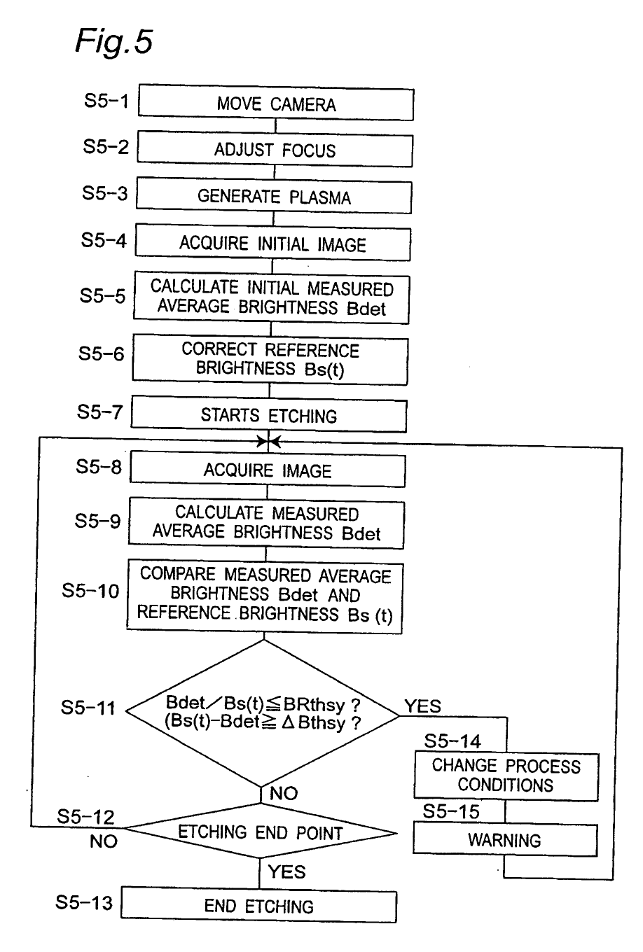

Referring to FIG. 5, at step S5-1, the camera 45 moves by the XY stage 46. Specifically, as shown in FIG. 3, the camera 45 is moved so that a desired position (area 67A in FIG. 6) on the substrate 1 inside the vacuum container 12 is put into the field of view through the window hole 42 of the casing 40, window hole 41 of the casing 35, gap 39A of the coil 36, and transparent section 30 of the dielectric plate 29. Then, at step S5-2, the focus of the camera 45 is adjusted. A laser is irradiated from the laser light source 47 to the surface of the substrate 1, and the reflected beam thereof is received by the camera 45 to be used for adjusting the focus. After that, at step S5-3, the high frequency voltage starts to be applied from the high frequency power supply for coil 38 to the coil 36 so as to generate plasma 70 in the internal space of the vacuum container 12. At the step S5-3, bias voltage has not yet been applied to the lower electrode 22, and etching as well has not yet started.

Then, at step S5-4, the camera 45 captures an image of the surface of the substrate 1 (initial image) in a status where plasma 70 is being generated but etching has not yet started. Further, at step S5-5, the brightness detection section 61 calculates the in-plane average brightness of the target area 68A in the initial image, i.e. the initial measured average brightness Bdet. Then, at step S5-6, the reference brightness storage section 62 corrects the reference brightness Bs(t) based on the initial measured average brightness Bdet. For example, if the initial measured average brightness Bdet is darker than a stored value of the reference brightness Bs(t) at the etching time t=0, then the reference brightness storage section 62 shifts the reference brightness Bs(t) to the lower brightness side, as shown by an arrow “A1” in FIG. 7.

After the above processes at steps S5-1 to 5-6 has been completed, at step S5-7, the bias voltage starts to be applied from the power supply for bias 23 to the lower electrode 22 to start dry etching of the substrate 1. During the dry etching, portions of the substrate 1 not coated with the resist mask 2 but exposed to the plasma 70 are etched by F radicals as etching species, positive ions (S ions, O ions or the like), and the He component. The O component reacts with the Si atoms of the substrate 1, and forms a side wall protective film of SiO₂.

The inner face 29b of the dielectric plate 29 made of quartz is gradually etched if the status of being exposed to the plasma 70 continues. However in the present embodiment, the window plate 34 made of sapphire is fixed to the lower polished section 32 of the inner face 29b of the dielectric plate 29, so as to prevent a drop in transparency or cloudiness of the transparent section 30 of the dielectric plate 29. Sapphire is a material having high transparency, and a strong resistance to the plasma of gas normally used for plasma processing, such as F gas, Cl gas and Br gas. Therefore a window plate 34 made of sapphire does not generate a drop in transparency or cloudiness even if a status of being exposed to the plasma 70 continues, and the transparent section 30 maintains an appropriate transparency. Since the transparent section 30 maintains an appropriate transparency, the camera 45 can capture an image of the substrate 1 in the vacuum 12 at good quality through the transparent section 30.

During etching, the processes at steps S5-8-S5-12 are repeated with a sufficiently short time space. First, at step S5-8, the camera 45 captures an image of the surface (area 67A) of the substrate 1. Then, at step S5-9, the brightness detection section 61 calculates the measured average brightness Bdet of the target area 68A based on the image captured by the camera 45. Then in step S5-10, the comparison section 63A compares the measured average brightness Bdet and the reference brightness Bs(t). Specifically, the comparison section 63A determines a quotient resulting when the measured average brightness Bdet is divided by the reference brightness Bs(t) (Bdet/BS(t)). Further, at step S5-11, the judgment section 64A judges whether there is the indication of the generation of black silicon based on the quotient calculated by the comparison section 63A in step S5-10 and the brightness ratio threshold BRthsy.

If the above Expression (1) is not established in step S5-11, that is, if the judgment section 64A judged that there is no indication of the generation of black silicon, then it is judged whether the etching process reaches an end point at step S5-12. The end point of etching can be judged by receiving the laser irradiated from the laser light source 47 to the substrate 1 by the camera 45 to measure the etching depth. The end point of etching can also be judged by the etching time. If the end point of etching is detected at step S5-12, then the etching process ends at step S5-13. On the other hand, if the end point of etching is not detected at step S5-12, the processes at steps S5-8 to S5-11 are repeated.

If expression (1) is established in the above step S5-11, that is, if the judgment section 64A judges that there is the indication of the generation of black silicon, then the apparatus control section 54 changes the process conditions into conditions whereby priority is given to the prevention of the generation of black silicon rather than to the selection ratio at step S5-4. Also if it is judged that there is the indication of the generation of black silicon, then the warning light 50 is turned ON or a predetermined message is displayed on the display section 49 at step S5-15, so as to notify the operator that there is an indication of the generation of black silicon.

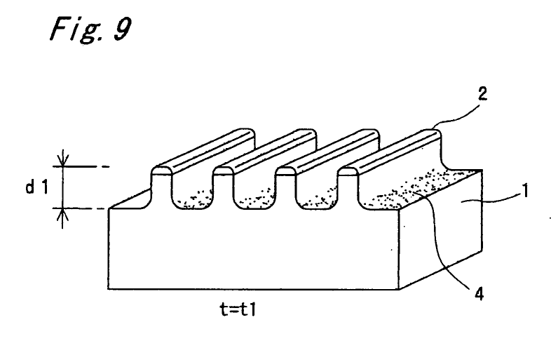

When the measured average brightness Bdet changes, as shown in FIG. 7, and the measured average brightness Bdet drops down to 180 at the point of etching time t1, Bdet/Bs(t) calculated in step S5-10 becomes lower than 0.8 (brightness ratio threshold), so it is judged in step S5-11 that there is an indication of the generation of black silicon. In this case, a certain amount of SiO₂ deposit 4 exists on the base of the trenches 7, as shown in FIG. 9, at the point of etching time ti, and this deposit 4 drops the measured average brightness Bdet. In other words, the monitoring section 57 judges whether there is an indication of the generation of black silicon based on the drop in brightness on the surface of the substrate 1 by the deposit 4 generated at the base of the trenches 7.

The change of the process conditions when it is judged that there is an indication of the generation of black silicon (step S5-14) will be described.

Firstly, the generation of black silicon can be suppressed by increasing the bias voltage to be applied from the power supply for bias 23 to the lower electrode 22. In the present embodiment, the initial value of the power of the bias voltage is 50 W, and the generation of black silicon can be suppressed by increasing this to 80 W, for example. If the bias voltage is increased, then the speed of ions which collide with the base of the trenches 7 increases. In other words, the energy of ion collision increases by increasing the bias voltage. As a result, the SiO₂ deposit 4 can be sputtered from the base of the trenches 7 by a sputtering method. If the bias voltage is too high, on the other hand, the resist mask 2 tends to be damaged by ions, and the selective ratio drops. Therefore if no indication of the generation of black silicon is detected, the bias voltage is set low, assigning priority to the selection ratio (50 W in the case of the present embodiment), and the bias voltage is increased only when an indication of the generation of black silicon is detected (80 W in the case of the present embodiment), thereby both the appropriate selection ratio and the prevention of the generation of black silicon can be implemented.

Secondly, the generation of black silicon can be suppressed by decreasing the pressure in the internal space 15 of the vacuum container 12. The initial value of the pressure is 30 Pa in the case of the present embodiment, and the generation of black silicon can be suppressed by decreasing the pressure down to 25 Pa, for example. If the pressure inside the vacuum container 12 is decreased, the time of the etching gas remaining in the vacuum container 12 is decreased, so the etching gas is exhausted out of the vacuum container 12 before excessive SiO₂ deposits 4 are formed on the base of the trenches 7. If the pressure inside the vacuum container 12 is low, on the other hand, the speed of ions increases, so the resist mask 2 tends to be damaged, and the selection ratio drops. Therefore if no indication of the generation of black silicon is detected, the pressure is set high, assigning priority to the selection ratio (30 Pa in the case of the present embodiment), and the pressure is set low only when an indication of the generation of black silicon is detected (25 Pa in the case of the present embodiment), thereby both the appropriate selective ratio and the prevention of the generation of black silicon can be implemented.

Thirdly, the generation of black silicon can be suppressed by decreasing the ratio of the O₂ gas in the etching gas. In the present embodiment, the initial value of the supply flow rate of O₂ gas is 40 sccm, and the generation of black silicon can be suppressed by decreasing the supply flow rate to 20 sccm, for example. Black silicon is caused by SiO₂ deposits 4, so if the supply flow rate of the O₂ gas to the vacuum container 12 is decreased so as to decrease the O component in the vacuum container 12, the generation of SiO₂ deposits 4 is suppressed. On the other hand, if the supply flow rate of O₂ gas to the vacuum container 12 is decreased, the formation of the side wall protective layer made of SiO₂ is also suppressed, so maintaining the side walls of the trenches in a vertical shape becomes difficult. Therefore if no indication of the generation of black silicon is detected, the supply flow rate of O₂ gas is set high (40 sccm in the case of the present embodiment), assigning priority to the formation of the side wall protective layer, and the supply flow rate of O₂ gas is decreased only when an indication of the generation of black silicon is detected (20 sccm in the case of the present embodiment), thereby both the profiles of the trenches 7 and the prevention of the generation of black silicon can be implemented.

By changing the process conditions as above, the generation of deposits 4 in the base of the trenches 7 is suppressed, and the generation of black silicon is prevented. One of increasing the bias voltage, decreasing the pressure of the vacuum container 12 and decreasing the supply flow rate of the O₂ gas can be executed, or two or more can be executed in combination.

If the change of the process conditions in step S5-14 is not executed, the amount of deposits 4 in the base of the trenches 7 increases, so the measured average brightness Bdet drops continuously even after the etching time t1, as shown by the solid line in FIG. 7. But if the change of process conditions in step S5-14 is executed and the generation of deposits 4 in the base of the trenches 7 is suppressed, the measured average brightness Bdet after the etching time t1 gently drops relatively, as shown by the two dot chain line in FIG. 7.

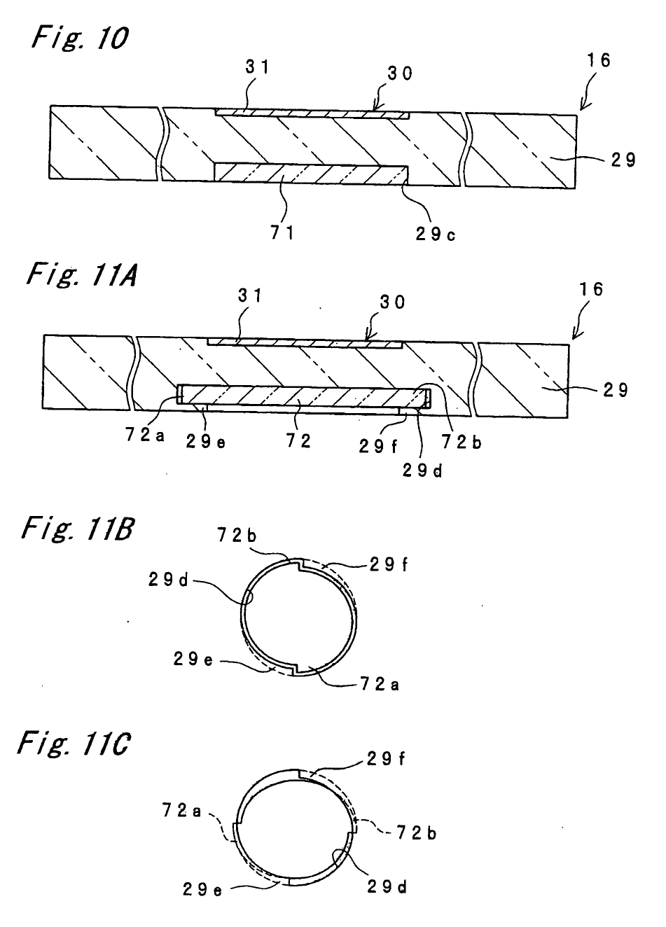

FIGS. 10 to 13 show alternatives of the top wall 16 of the vacuum container 12.

The top wall 16 in the first alternative shown in FIG. 10 is comprised of a dielectric plate 29 made of quartz. A circular concave section 29c is formed in the inner face 29b of the dielectric plate 29 in a bottom view, and a disk type window plate 71 made of sapphire is inserted in and fixed to this concave section 29c. An upper polished section 31 on an outer face 29a of the dielectric plate 29 and the window plate 71 inserted in the inner face 29b function as a transparent section 30.

The top wall 16 in the second alternative shown in FIGS. 11A to 11C is also comprised of a dielectric plate 29 made of quartz. A holding hole 29d for removeably holding a window plate 72 made of sapphire is formed in an inner face 29b of the dielectric plate 29. The holding hole 29d is roughly a circular hole with a base in a bottom view, and a pair of engaging sections 29e and 29f, protruding inward, is formed at the opening edge. The window plate 72, on the other hand, is roughly a disk shape, and has a pair of engaged sections 72a and 72b which protrude outward. As shown in FIG. 11B, the window plate 72 is attached/detached to/from the holding hole 29d if the engaged sections 72a and 72b are in positions that do not interfere with the engaging sections 29e and 29d of the holing hole 29d. On the other hand, as shown in FIG. 11C, the window plate 72 can be held in the holding hole 29d if the engaged sections 72a and 72b come on to the engaging sections 29e and 29d. The upper polished section 31 of the outer face 29a of the dielectric plate 29 and the window plate 72 function as a transparent section 30.

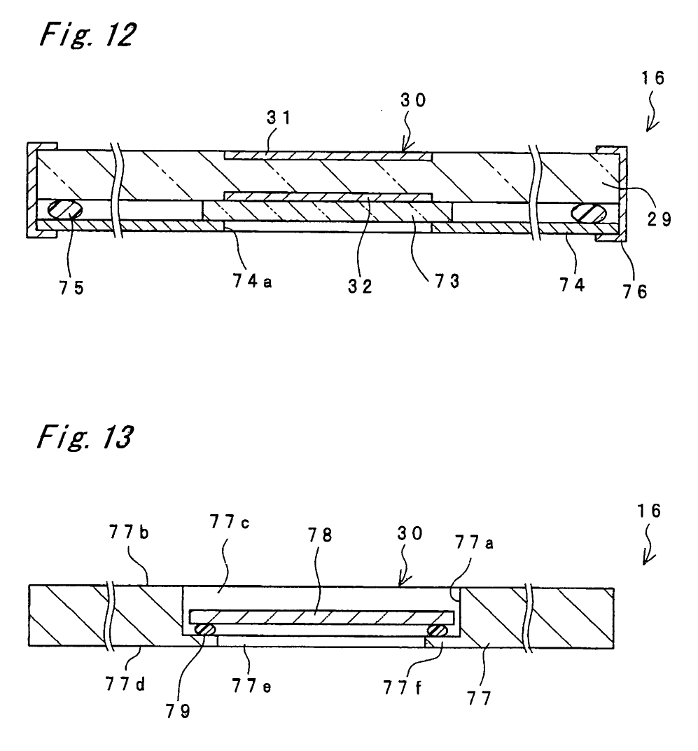

The top wall 16 of the third alternative shown in FIG. 12 is comprised of a dielectric plate 29 made of quartz, where the top and lower polished sections 31 and 32 are formed on an outer face 29a and an inner face 29b, a window plate 73 made of sapphire, a holding plate 74 which is a ceramic (Al₂O₃) thin plate, an O ring 75 and a clamp 76. A window hole 74a is formed in the holding plate 74 penetrating in the plate thickness direction. The window plate 73 is disposed contacting the lower polished section 32 of the inner face 29b of the dielectric plate 29. The holding plate 74 is pressed against the dielectric plate 29 by the clamp 76 via an O ring 75, so that the window hole 74a corresponds to the window plate 73. The window plate 73 is fixed to the inner face 29b of the dielectric plate 29 by being inserted between the dielectric plate 29 and the holding plate 74. The top and lower polished sections 31 and 32 of the dielectric plate 29, the window plate 73 and the window hole 74a of the holding plate 74 function as a transparent section 30.

The top wall 16 of the fourth alternative shown in FIG. 13 is a plate 77 made of ceramic. A hole 77a with steps is formed in the plate 77 penetrating in the plate thickness direction. In the hole 77a, a second portion 77e at the inner face 77d side of the plate 77 has a smaller diameter than the first portion 77c at the outer face 77b side, and a support section 77f, which protrudes inward, is formed at the inner face 77d side. In the hole 77a, a window plate 78 made of sapphire is inserted from the outer face 77b side. The window plate 78 is supported by the support section 77f via the O ring 79.

The present invention was described using an inductive coupled dry etching processing device, but the present invention can also be applied to other plasma processing apparatuses, such as dry etching apparatuses, sputtering apparatuses and plasma CVDs.

The present invention was completely described with reference to the accompanying drawings, but various changes and modifications are possible by experts skilled in the art. Such changes and modifications shall be included in the present invention as long as they do not depart from the spirit and scope of the present invention.

1-5. (canceled)

6. A dry etching apparatus, comprising:
a vacuum chamber in an internal space of which a processing target made of silicon material is disposed at a bottom wall side;
a coil for generating plasma disposed outside and above the vacuum chamber and provided with conductors arranged so that a gap is formed in a plane view;
a top wall of the vacuum chamber closing a top of the internal space and provided with a transparent section at a position corresponding to the gap between the conductors of the coil in the plane view;
an imaging device disposed above the coil, being capable of putting at least a part of the processing target into a field of view thereof through the gap between the conductors of the coil and the transparent section of the top wall, and obtaining an image of an etched surface of the processing target under dry etching by the plasma generated in the internal space; and
a monitoring section for monitoring indication of generation of black silicon base on the obtained image.

7. The dry etching apparatus according to claim 6, wherein the monitoring section comprises a brightness detection section for calculating measured brightness which is brightness at a predetermined measurement spot on the etched surface of the processing target, and monitoring the indication of the generation of back silicon base on the measured brightness.

8. The dry etching apparatus according to claim 7, wherein the monitoring section further comprises:
a reference brightness storage section for storing a reference brightness which is brightness at the measurement spot corresponding to passage of time from a start of the dry etching where the black silicon is not generated;
a comparison section for comparing the measured brightness calculated by the brightness detection section and the reference brightness stored by the reference brightness storage section; and
a judgment section for judging whether the indication of the generation of the back silicon exists or not based on the comparison result by the comparison section.

9. The dry etching apparatus according to claim 8, further comprising an apparatus control section for changing condition for dry etching when the judgment section judges that the indication of the generation of the black silicon exists.

10. The dry etching apparatus according to claim 6, wherein the transparent section further comprises a window plate made of sapphire installed in an inner surface of the plate located at the internal side at the portion corresponding to the gap between the conductors of the coil in the plane view.

11. The dry etching apparatus according to claim 6, further comprising a moving mechanism for horizontally moving the imaging device above the coil.

12. A method for dry etching of a substrate made of silicon material, comprising:
obtaining an image of an etched surface of the substrate under dry etching; and
monitoring indication of generation of black silicon based on the obtained image.

13. The method according to claim 12, wherein the monitoring comprising:
calculating measured brightness which is brightness at a predetermined measurement spot on the etched surface of the substrate based on the obtained image; and
using the measured brightness for monitoring the indication of the generation of the black silicon.

14. The method according to claim 13, wherein the measured brightness is compared with reference brightness which is brightness corresponding to passage of time from a start of the dry etching where the back silicon is not generated.

15. The method according to claim 14, wherein if a ratio of the measured brightness with respect to the reference brightness becomes equal to or less than a predetermined ratio, then it is judged that the indication of the generation of the black silicon exists.

16. The method according to claim 14, wherein if the measured brightness becomes less than the reference brightness by a predetermined difference in brightness or more, then it is judged that the indication of the generation of the black silicon exists.

17. The method according to claim 14, further comprising changing condition for dry etching when the existence of the indication of the generation of the black silicon is judged.

18. The method according to claim 17, wherein the changing of the condition for dry etching includes increasing a bias voltage applied to a lower electrode on which the substrate is mounted.

19. The method according to claim 17, wherein the changing of the condition for dry etching includes decreasing a pressure in a vacuum container within which the substrate is accommodated.

20. The method according to claim 17, wherein an etching gas includes at least SF₆, O₂, and He, and
wherein the changing to the condition for dry etching includes decreasing rate of content of O₂ in the etching gas.
